(19) United States
(12) Patent Application Publication
(10) Pub. No.: US 2026/0055500 A1
(43) Pub. Date: Feb. 26, 2026

(54) SPUTTERING APPARATUS

(71) Applicant: Japan Display Inc., Tokyo (JP)

(72) Inventor: Ken SUGITA, Tokyo (JP)

(73) Assignee: Japan Display Inc., Tokyo (JP)

(21) Appl. No.: 19/378,454

(22) Filed: Nov. 4, 2025

Related U.S. Application Data
(63) Continuation of application No. PCT/JP2024/018542, filed on May 20, 2024.

(30) Foreign Application Priority Data
Jun. 13, 2023 (JP) 2023-097119

(51) Int. Cl. C23C 14/34; C23C 14/50

(52) U.S. Cl. CPC C23C 14/3407; C23C 14/50

(57) ABSTRACT

A sputtering apparatus includes: a substrate hold portion holding a substrate; a target facing the substrate hold portion and configured to move to a first direction in a relative positional relationship with the substrate hold portion; and a plurality of radical irradiation apparatuses, irradiation positions of radicals from the plurality of radical irradiation apparatuses on a deposition surface of the substrate being different, wherein the plurality of radical irradiation apparatuses is configured to individually adjust an amount of radical generation.

### CROSS REFERENCE TO RELATED APPLICATIONS

This application is a Continuation of International Patent Application No. PCT/JP2024/018542, filed on May 20, 2024, which claims the benefit of priority to Japanese Patent Application No. 2023-097119 filed on Jun. 13, 2023, the entire contents of which are incorporated herein by reference.

### FIELD

An embodiment of the present invention relates to a sputtering apparatus. In particular, an embodiment of the present invention relates to a sputtering apparatus provided with a radical irradiation apparatus.

### BACKGROUND

In small and medium sized display devices such as smartphones, display devices using liquid crystal or OLED's (Organic Light Emitting Diode) have already been commercialized. Among these, an OLED display device using OLED's, which is a self-luminous element, has the advantage of having high contrast and not requiring a backlight, as compared with a liquid crystal display device. However, since an OLED is composed of an organic compound, it is difficult to ensure high reliability of the OLED display device due to degradation of the organic compound.

In recent years, as a next-generation display device, a so-called micro LED display device or mini LED display device in which a minute LED chip is mounted in a pixel of a circuit substrate has been developed. An LED is a self-luminous element similar to an OLED. However, unlike OLED's, an LED is composed of a stable inorganic compound including gallium (Ga) or indium (In). Therefore, compared with an OLED display device, it is easy to ensure a micro LED display device having high reliability. An LED chip has high luminous efficiency and can realize high brightness. Therefore, the micro LED display device or mini LED display device is expected to be a next-generation display device with high reliability, high brightness, and high contrast.

Incidentally, a gallium nitride film used in the micro LED and the like is generally deposited on a sapphire substrate at a high temperature of 800° C. to 1000° C. using MOCVD (Metal Organic Chemical Vapor Deposition) or HVPE (Hydride Vapor Phase Epitaxy). However, in recent years, a method for depositing a gallium nitride film by sputtering, which enables deposition at relatively low temperatures, has been developed (for example, see Japanese laid-open patent publication No. 2012-119569).

### SUMMARY

A sputtering apparatus according to an embodiment of the present invention includes: a substrate hold portion holding a substrate; a target facing the substrate hold portion and configured to move to a first direction in a relative positional relationship with the substrate hold portion; and a plurality of radical irradiation apparatuses, irradiation positions of radicals from the plurality of radical irradiation apparatuses on a deposition surface of the substrate being different, wherein the plurality of radical irradiation apparatuses is configured to individually adjust an amount of radical generation.

### BRIEF DESCRIPTION OF DRAWINGS

FIG. 1 is a top view showing an overview of a sputtering apparatus according to an embodiment of the present invention.

FIG. 2 is a side view showing an overview of a sputtering apparatus according to an embodiment of the present invention.

FIG. 3 is a top view showing an overview of a sputtering apparatus showing a modification of an embodiment of the present invention.

FIG. 4A is a diagram illustrating a sputtering method according to an embodiment of the present invention.

FIG. 4B is a diagram illustrating a sputtering method according to an embodiment of the present invention.

FIG. 4C is a diagram illustrating a sputtering method according to an embodiment of the present invention.

FIG. 4D is a diagram illustrating a sputtering method according to an embodiment of the present invention.

FIG. 5A is a diagram illustrating a sputtering method according to an embodiment of the present invention.

FIG. 5B is a diagram illustrating a sputtering method according to an embodiment of the present invention.

FIG. 5C is a diagram illustrating a sputtering method according to an embodiment of the present invention.

FIG. 5D is a diagram illustrating a sputtering method according to an embodiment of the present invention.

### DESCRIPTION OF EMBODIMENTS

Hereinafter, embodiments of the present invention will be described with reference to the drawings. The following invention is merely an example. A configuration that can be easily conceived by a person skilled in the art by appropriately changing the configuration of the embodiment while keeping the gist of the invention is naturally included in the scope of the present invention. In the drawings, the widths, thicknesses, shapes, and the like of the respective portions may be schematically represented in comparison with actual embodiments to make the description clearer. However, the illustrated shapes are merely examples, and do not limit the interpretation of the present invention. In the present specification and the drawings, the same reference signs are given to elements similar to those previously described with respect to the previous drawings, and detailed description thereof may be omitted as appropriate.

In the embodiments of the present invention, a direction from a first member toward a second member is referred to as “on” or “above. ” Conversely, a direction from the second member toward the first member is referred to as “under” or “below. ” In this way, for convenience of explanation, the phrase “above” or “below” is used for description, but for example, the first member and the second member may be arranged so that the vertical relationship is opposite to that shown in the figure. In the following explanation, for example, the expression “the second member on the first member” merely describes the vertical relationship between the first member and the second member as described above, and another member may be arranged between the first member and the second member. Above or below means a stacking order in a structure in which a plurality of layers is stacked, and the expression “the second member above the first member” may be a positional relationship in which the first member and the second member do not overlap. On the other hand, the second member vertically above the first member indicates a positional relationship in which the first member and the second member overlap each other.

Furthermore, in the present specification, the expressions “α includes A, B or C,” “α includes any of A, B and C,” and “α includes one selected from a group consisting of A, B, and C” do not exclude the case where α includes a plurality of combinations of A to C unless otherwise specified. Furthermore, these expressions do not exclude the case where α includes other elements.

The following embodiments can be combined as long as there is no technical contradiction.

If a gallium nitride layer forming a micro LED can be deposited at a low temperature, the micro LED can be directly formed on a glass substrate. The micro LED is formed by stacking a plurality of films having differing compositions. In a conventional sputtering apparatus, it is necessary to prepare a target and a chamber for films having different compositions.

An object of an embodiment of the present invention is to provide a new sputtering apparatus in view of the above problem.

### 1. First Embodiment

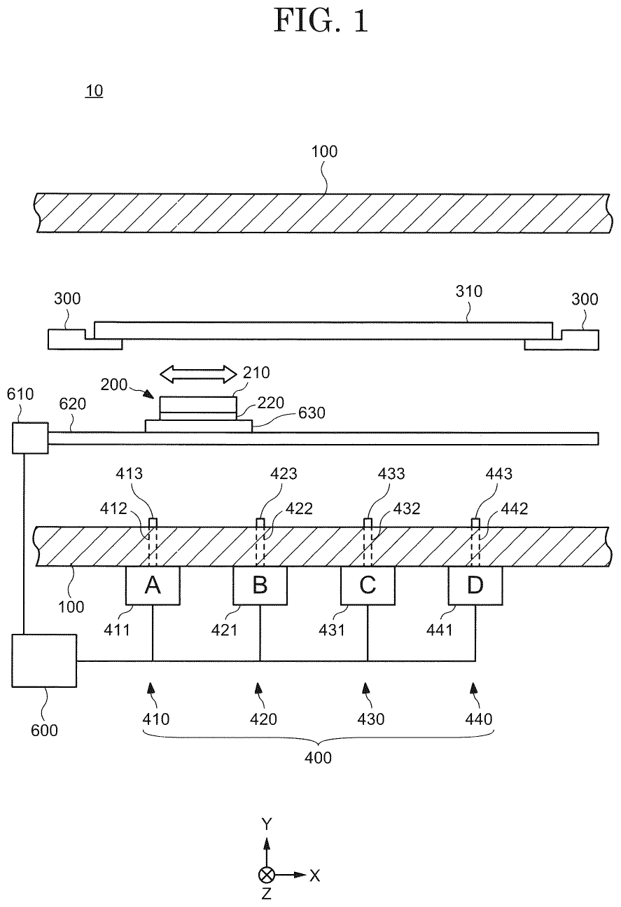

A sputtering apparatus 10 according to an embodiment of the present invention and a sputtering method using the sputtering apparatus 10 will be described with reference to FIG. 1 to FIG. 3.

### [1-1. Configuration of Sputtering Apparatus]

FIG. 1 is a top view showing an overview of a sputtering apparatus according to an embodiment of the present invention. As shown in FIG. 1, the sputtering apparatus 10 includes a chamber 100, a target portion 200, a substrate hold portion 300, a radical irradiation apparatus 400, a control device 600, a position control device 610, and a moving mechanism 620. In FIG. 1, a portion of the chamber 100 is shown. The chamber 100 forms a closed space. Although not shown, an exhaust port and a process gas supply port are provided in the chamber 100. The pressure inside the chamber 100 can be reduced through the exhaust port. Gases such as argon and nitrogen required for sputtering can be supplied into the chamber 100 via the process gas supply port.

A substrate 310 to be deposited is held by the substrate hold portion 300. In FIG. 1, the substrate 310 is held by the substrate hold portion 300 so that the main surface (deposition surface) of the substrate 310 expands in an X-axis direction and a Z-axis direction. In other words, the substrate 310 is held in the substrate hold portion 300 in the vertical position. The X-axis direction may be referred to as a “first direction. ” The Z-axis direction may be referred to as a “second direction. ” A Y-axis direction may be referred to as a “third direction. ”

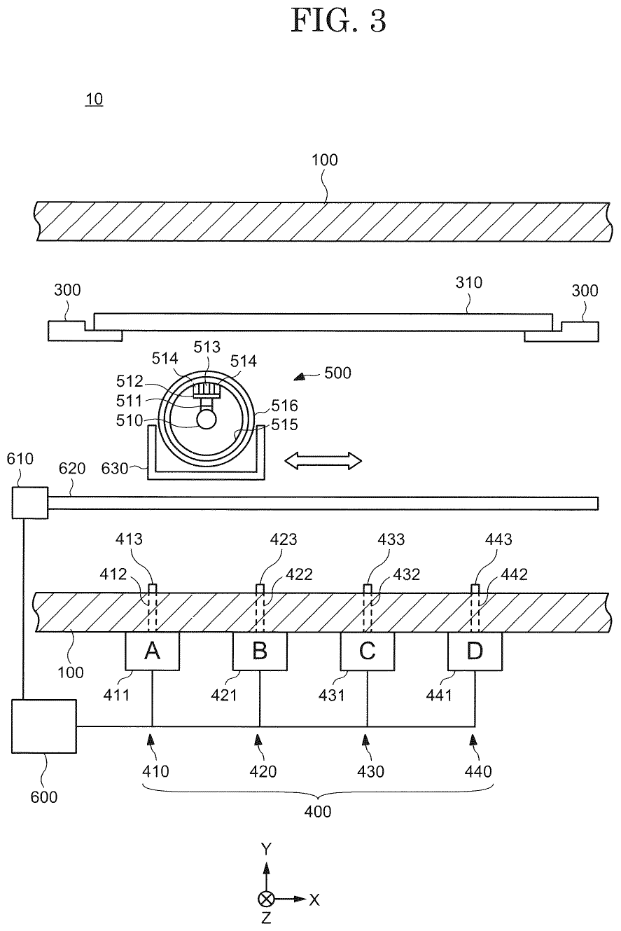

The target portion 200 is arranged to face the substrate hold portion 300. The target portion 200 includes a target 210 and a backing plate 220. Although details will be described later, the target 210 is a flat plate type target with a longitudinal axis in the Z-axis direction (FIG. 3). The target 210 is composed of the same material as a thin film formed on the deposition surface of the substrate 310, or a material containing an element contained in the thin film. For example, in the case where a gallium nitride (GaN) thin film is deposited on the deposition surface, the target 210 is composed of GaN or gallium (Ga). A side facing the substrate hold portion 300 with respect to the target portion 200 is referred to as a front surface, and a side facing the radical irradiation apparatus 400 with respect to the target portion 200 is referred to as a back surface. For example, the target 210 is fixed to the front surface of the backing plate 220 by indium or the like.

A member (not shown) such as a magnet is provided on the back surface of the backing plate 220. Since the magnet confines electrons in a plasma, a high-density plasma region is formed on the front surface side of the target 210. In the plasma region, a process gas is ionized. For example, argon is used as the process gas. The ionized argon is accelerated toward the target 210 in a sheath region formed between the plasma region and the target 210. The argon ion accelerated in this way collides with the target 210, and the target material is sputtered.

In addition to the above GaN and Ga, materials such as aluminum, aluminum nitride, indium, indium nitride, silicon, and silicon nitride are used as the target 210. A material in which an impurity (dopant) is introduced into the above material may be used as the target 210. For example, a material in which magnesium or silicon is introduced as a dopant into gallium nitride may be used. Gallium nitride containing magnesium as a dopant functions as a P-type semiconductor. Gallium nitride containing silicon as a dopant functions as an N-type semiconductor.

A holding mechanism 630 for holding the target portion 200 is provided on the back surface side of the backing plate 220. The holding mechanism 630 is arranged in the moving mechanism 620. The moving mechanism 620 controls the positions of the holding mechanism 630 and the target portion 200 in the X-axis direction. For example, a rail mechanism is used as the moving mechanism 620. However, another mechanism may be used as the moving mechanism 620. The moving mechanism 620 is provided with the position control device 610. The position control device 610 detects the positions of the holding mechanism 630 and the target portion 200 in the X-axis direction controlled by the moving mechanism 620. For example, a rotary encoder is used as the position control device 610.

The position control device 610 is connected to the control device 600. Based on a control signal from the control device 600, the position control device 610 controls the moving mechanism 620, and the positions of the holding mechanism 630 and the target portion 200 in the X-axis direction are determined. Further, the control device 600 obtains current position information of the holding mechanism 630 and the target portion 200 in the X-axis from the position control device 610. The control device 600 is connected to the radical irradiation apparatus 400 (radical irradiation apparatuses 410 to 440), which will be described later. Although details will be described later, the control device 600 controls the amount or types of radicals generated by the radical irradiation devices 410 to 440.

The target portion 200 is movable, and a relative positional relationship between the target portion 200 and the substrate hold portion 300 changes in the X-axis direction. In the example of FIG. 1, the position of the substrate hold portion 300 is fixed in the X-axis direction, and the position of the target portion 200 moves. The movement of the target portion 200 in the X-axis direction may be a swing motion (reciprocating or repeating in the positive and negative directions in the X-axis) or a unidirectional passage. However, the position of the target portion 200 may be fixed in the X-axis direction, the position of the substrate hold portion 300 may be moved, or both the target portion 200 and the substrate hold portion 300 may move as described above.

The radical irradiation apparatus 400 is provided on the side wall of the chamber 100. In the present embodiment, the radical irradiation apparatus 400 includes a radical irradiation apparatus 410(A), a radical irradiation apparatus 420(B), a radical irradiation apparatus 430(C), and a radical irradiation apparatus 440(D). The radical irradiation devices 410 to 440 are all arranged to irradiate radicals onto the deposition surface of the substrate 310. In the X-axis direction, the radical irradiation positions by the radical irradiation apparatuses 410 to 440 are different. In the present embodiment, the above radical irradiation positions are realized by arranging the radical irradiation apparatuses 410 to 440 side by side in the X-axis direction.

The radical irradiation apparatus 410 includes a radical generator 411, a pipe 412, and a radical outlet 413. The radical irradiation apparatus 420 includes a radical generator 421, a pipe 422, and a radical outlet 423. The radical irradiation apparatus 430 includes a radical generator 431, a pipe 432, and a radical outlet 433. The radical irradiation device 440 includes a radical generator 441, a pipe 442, and a radical outlet 443. The radical generators 411 to 441 are provided outside the chamber 100. The pipes 412 to 442 are connected to the radical generators 411 to 441, respectively, and penetrate the sidewall of the chamber 100, respectively. The radical outlets 413 to 443 are connected to the pipes 412 to 442, respectively, and are provided inside the chamber 100.

Plasma power sources (for example, microwave power sources) provided in the radical generators 411 to 441 are controlled to be in an on-state while the process gas is supplied to the radical irradiation devices 410 to 440, so that plasma is generated inside the radical generators 411 to 441, and the radical caused by the process gas is generated. By controlling the electric power supplied to the plasma power sources, the amount of radical generation can be adjusted.

The radicals generated by the radical generators 411 to 441 are guided into the chamber 100 through the pipes 412 to 442 and are released into the chamber 100 from the radical outlets 413 to 443.

For Example, the process gas supplied to the radical irradiation devices 410 to 440 is hydrogen (H₂) gas, ammonia (NH₃) gas, or nitrogen (N₂) gas. For example, in a state where hydrogen gas is supplied to the radical irradiation apparatus 410 and a hydrogen radical is supplied into the chamber 100, ammonia gas is supplied to the radical irradiation apparatus 420, and an ammonia radical is supplied into the chamber 100. When the ammonia radical reaches the thin film deposited on the deposition surface of the substrate 310, the thin film is nitrided. The hydrogen radical promotes nitridation of the thin film by abstracting hydrogen from the ammonia radical. A gas other than the above may be used as the gas to be supplied to the radical irradiation apparatus 400.

The radical irradiation apparatuses 410 to 440 can individually adjust the amount of radical generation. The radical irradiation devices 410 to 440 may irradiate the substrate 310 with the same type of radicals, and at least some of the radical irradiation apparatuses may irradiate the substrate 310 with different types of radicals from the other radical irradiation apparatuses. In this case, some radical irradiation apparatuses are supplied with a gas different from the gas supplied to the other radical irradiation apparatuses. The radical irradiation apparatus 410 may be referred to as a “first radical irradiation apparatus. ” The radical irradiation apparatus 420 adjacent to the radical irradiation apparatus 410 may be referred to as a “second radical irradiation apparatus. ”

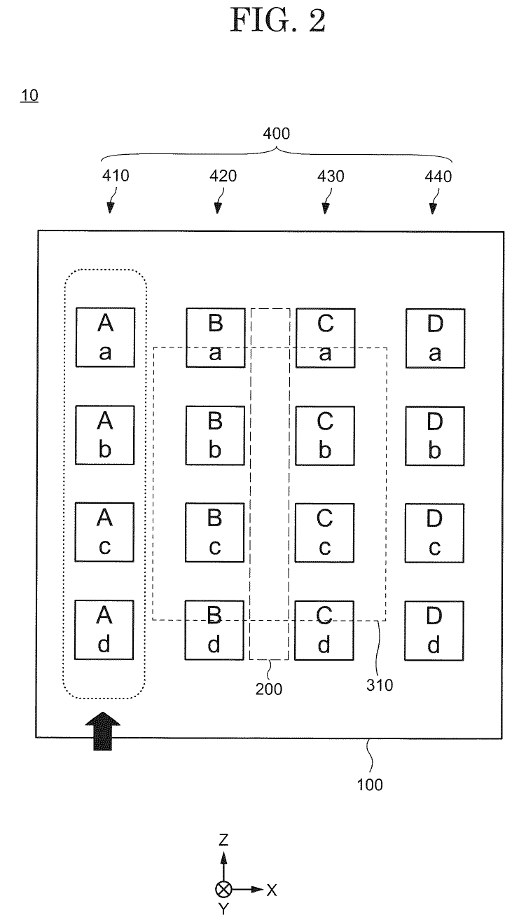

FIG. 2 is a side view showing an overview of a sputtering apparatus according to an embodiment of the present invention. FIG. 2 is a diagram of the sputtering apparatus 10 viewed in the Y-axis direction. As shown in FIG. 2, the radical irradiation apparatuses 410 to 440 are arranged in a matrix in the X-axis direction and the Z-axis direction. In the following description, the X-axis direction may be referred to as a row direction, and the Z-axis direction may be referred to as a column direction.

The radical irradiation apparatus 410 includes radical irradiation apparatuses Aa, Ab, Ac, and Ad. The radical irradiation apparatuses Aa, Ab, Ac, and Ad are arranged side by side in the Z-axis direction, and the amount of radical generation can be individually adjusted. The radical irradiation apparatus Aa, Ab, Ac, and Ad may irradiate the substrate 310 with the same type of radicals, and at least some of the radical irradiation apparatuses may irradiate the substrate 310 with different types of radicals from the other radical irradiation apparatuses.

The radical irradiation apparatus 420 includes radical irradiation apparatuses Ba, Bb, Bc, and Bd. The radical irradiation apparatuses Ba, Bb, Bc, and Bd are arranged side by side in the Z-axis direction, and the amount of radical generation can be individually adjusted. The radical irradiation apparatuses Ba, Bb, Bc, and Bd may irradiate the substrate 310 with the same type of radicals, and at least some of the radical irradiation apparatuses may irradiate the substrate 310 with different types of radicals from the other radical irradiation apparatuses.

The radical irradiation apparatus 430 includes a radical irradiation apparatus Ca, Cb, Cc, Cd. The radical irradiation apparatuses Ca, Cb, Cc, and Cd are arranged side by side in the Z-axis direction, and the amount of radical generation can be individually adjusted. The radical irradiation apparatuses Ca, Cb, Cc, and Cd may irradiate the substrate 310 with the same type of radicals, and at least some of the radical irradiation apparatuses may irradiate the substrate 310 with different types of radicals from the other radical irradiation apparatuses.

The radical irradiation apparatus 440 includes radical irradiation apparatuses Da, Db, Dc, and Dd. The radical irradiation apparatuses Da, Db, Dc, and Dd are arranged side by side in the Z-axis direction, and the amount of radical generation can be individually adjusted. The radical irradiation apparatuses Da, Db, Dc, and Dd may irradiate the substrate 310 with the same type of radicals, and at least some of the radical irradiation apparatuses may irradiate the substrate 310 with different types of radicals from the other radical irradiation apparatuses.

The radical irradiation apparatus Aa may be referred to as the “first radical irradiation apparatus,” the radical irradiation apparatus Ba may be referred to as the “second radical irradiation apparatus,” and the radical irradiation apparatus Ab may be referred to as a “third radical irradiation apparatus. ”

The radical irradiation apparatuses Aa˜Ad, the radical irradiation apparatuses Ba˜Bd, the radical irradiation apparatuses Ca˜Cd, and the radical irradiation apparatuses Da˜Dd may be referred to as “column-unit” radical irradiation apparatuses, respectively. That is, the column unit is a unit formed by a radical irradiation apparatus arranged in the Z-axis direction among the plurality of radical irradiation apparatuses. In this case, it can be said that the radical irradiation apparatuses in a plurality of column units are arranged side by side in the X-axis direction.

In the present embodiment, the column unit refers to one column of radical irradiation apparatuses, but a plurality of columns of radical irradiation apparatuses may be collectively defined as the column unit. For example, two columns of radical irradiation apparatuses may be collectively defined as the column unit.

Although details will be described later, when the deposition is performed on the substrate 310, the radical irradiation apparatus can be controlled for each column unit. For example, it is possible to control the radical irradiation apparatus so that the amount of radicals generated by the radical irradiation apparatus in a selected specific column unit (a first column unit) is greater than the amount of radicals generated by the radical irradiation apparatus in the other column units (a second column unit). For example, the radical irradiation apparatus can be controlled so that the amount of radicals generated by the radical irradiation apparatus in the other column units is 50% or less, 30% or less, 20% or less, or 10% or less of the amount of radicals generated by the radical irradiation apparatus in the selected specific column unit. In the above control process, the amount of radicals generated by the radical irradiation apparatus in the other column units may be zero. In the case where the amount of radical generation is zero, the radical irradiation apparatus in the other column units may be said to be in an off-state. In this case, it can be said that the radical irradiation apparatus of the selected specific column unit is in an on-state. The radical irradiation apparatuses of the specific column unit to be selected may be sequentially switched in the X-axis direction.

As described above, in the present embodiment, although a configuration in which the radical irradiation apparatus 400 emits radicals perpendicularly to the deposition surface of the substrate 310 on the back surface side of the target portion 200, the configuration is not limited to this configuration. For example, on the back surface side of the target portion 200, the radical irradiation apparatus 400 may be arranged to emit radicals from a direction inclined with respect to the deposition surface. Alternatively, the radical irradiation apparatus 400 may be arranged to emit radicals parallel to the deposition surface.

In the present embodiment, although the configuration in which one target portion 200 is provided for the substrate 310 is exemplified, a plurality of target portions 200 may be provided for the substrate 310.

### [1-2. Sputtering Method]

The sputtering apparatus 10 shown in FIG. 1 and FIG. 2 has a configuration in which individual radical irradiation apparatus can be individually controlled as described above, so that a high-quality thin film can be deposited.

For example, in a plan view of the deposition surface of the substrate 310, the quality of the deposited thin film may be improved by controlling the radical irradiation apparatus arranged in a region overlapping the target 210 to be in the off-state, controlling the radical irradiation apparatus arranged in a region not overlapping the target 210 to be in the on-state, or controlling the amount of radicals generated by the radical irradiation apparatus arranged in the region overlapping the target 210 to be smaller than the amount of radicals generated by the radical irradiation apparatus arranged in the region not overlapping the target 210.

Specifically, when a GaN layer is formed by a sputtering method using a GaN target, a nitrogen-depleted GaN layer tends to be formed. Even in such cases, after the GaN layer is deposited, the radical irradiation containing nitrogen (for example, the above ammonia radical irradiation and hydrogen radical irradiation) is performed on the GaN layer, whereby nitrogen can be replenished in the GaN layer. That is, the film quality of the GaN layer can be improved by the radical irradiation.

Alternatively, in the above plan view, the quality of the deposited thin film may be improved by controlling the radical irradiation apparatus arranged in the region overlapping the target 210 to be in the on-state, controlling the radical irradiation apparatus arranged in the region not overlapping the target 210 to be in the off-state, or controlling the amount of radicals generated by the radical irradiation apparatus arranged in the region overlapping the target 210 to be greater than the amount of radicals generated by the radical irradiation apparatus arranged in the region not overlapping the target 210.

Specifically, when the GaN layer is deposited by the sputtering method using a Ga target, the GaN layer can be formed by reactive sputtering in which nitrogen-containing radical irradiation is performed while depositing Ga atoms (or Ga clusters) sputtered from the substrate 310.

Alternatively, the on/off state of the radical irradiation apparatus or the amount of radical generation may be controlled according to the in-plane distribution of the thickness during deposition using the sputtering apparatus 10. For example, in the case where the thickness of the peripheral portion of the substrate 310 is greater than the thickness of the central portion, the amount of radicals generated by the radical irradiation apparatus corresponding to the peripheral portion can be controlled to be greater than the amount of radicals generated by the radical irradiation apparatus corresponding to the central portion. Since nitrogen can be replenished in both the central portion and the peripheral portion of the GaN layer by this control process, and the film quality of the GaN layer can be improved.

### [1-3. Modification of Sputtering Apparatus]

FIG. 3 is a top view showing an overview of a sputtering apparatus according to a modification of the embodiment of the present invention. Although a configuration in which a flat plate type target is used has been exemplified in FIG. 1, FIG. 3 shows a configuration in which a rotary target is used. Configurations of the substrate hold portion 300 and the radical irradiation apparatus 400 in FIG. 3 are similar to the configurations of the substrate hold portion 300 and the radical irradiation apparatus 400 in FIG. 1, so that the explanation thereof will be omitted.

As shown in FIG. 3, in the sputtering apparatus 10, a target portion 500 is provided in place of the target portion 200 of FIG. 1. The target portion 500 includes a support member 510, a fixing member 511, a yoke 512, a central magnet 513, a peripheral magnet 514, a backing tube 515, and a target 516. These members are shaped to have a longitudinal axis in the Z-axis direction.

The support member 510 is rotatably fixed to the chamber 100. The fixing member 511 is connected to the support member 510 and extends from the support member 510 toward the backing tube 515. The yoke 512 is fixed to an end portion of the fixing member 511. The central magnet 513 and the peripheral magnet 514 are fixed to the yoke 512 and extend from the yoke 512 toward the backing tube 515. End portions of the central magnet 513 and the peripheral magnet 514 on the backing tube 515 side have a curved shape along the inner wall of the backing tube 515.

The central magnet 513 and the peripheral magnet 514 have a linear shape extending in the Z-axis direction. The central magnet 513 and the peripheral magnet 514 rotate about the support member 510 along the inner wall of the backing tube 515. The support member 510 is fixed to the fixing member 511 and rotates with the central magnet 513 and the peripheral magnet 514. However, the support member 510 may be fixed to the chamber 100 without rotating. In this case, the fixing member 511 is rotatably connected to the support member 510.

The target 516 is fixed to the backing tube 515. The backing tube 515 and the target 516 have a cylindrical shape about an axis extending in the Z-axis direction, and rotate about the support member 510. The target 516 rotates independently of the central magnet 513 and the peripheral magnet 514. In the case where the central magnet 513 and the peripheral magnet 514 are not specifically distinguished, they may be simply referred to as “magnets. ”

The central magnet 513 has a different polarity from the peripheral magnet 514. That is, these magnets form a magnetic field from the central magnet 513 to the peripheral magnet 514 (or to the opposite direction). This magnetic field confines electrons in the plasma, so that the high-density plasma region is formed in a region corresponding to the region between the central magnet 513 and the peripheral magnet 514. In the plasma region, the process gas is ionized. For example, argon is used as the process gas. The ionized argon is accelerated toward the target 516 in a sheath region formed between the plasma region and the target 516. The argon ion accelerated in this way collides with the target 516, and the target material is sputtered.

As described above, according to the sputtering apparatus 10 of the present embodiment, since the amount and types of radicals generated in the radical irradiation apparatus 400 arranged in the row and column directions are variable, appropriate radical irradiation conditions can be selected according to the characteristics of the sputtering apparatus and the film type to be deposited.

### 2. Second Embodiment

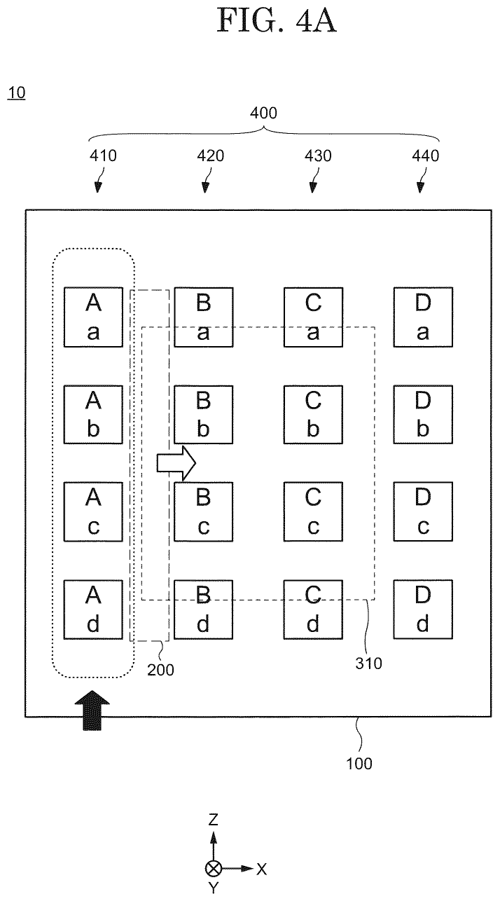

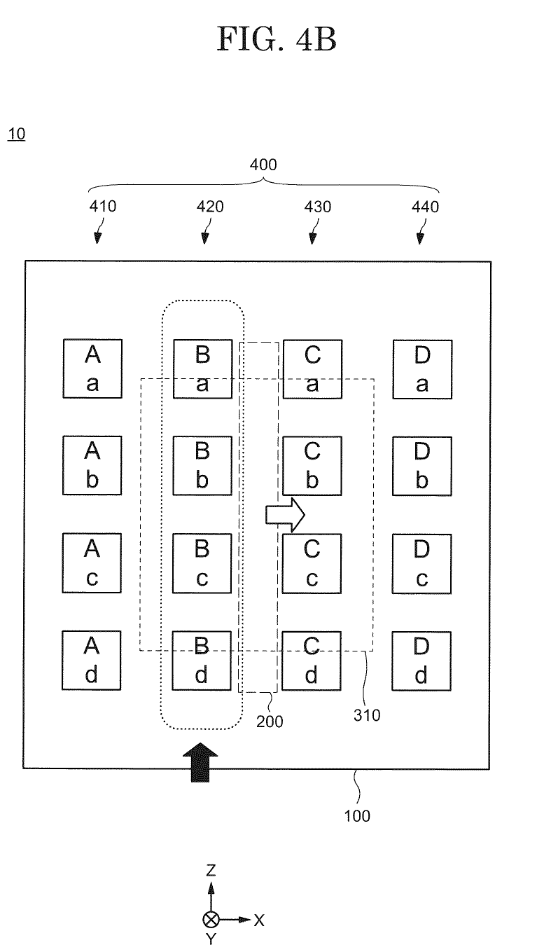

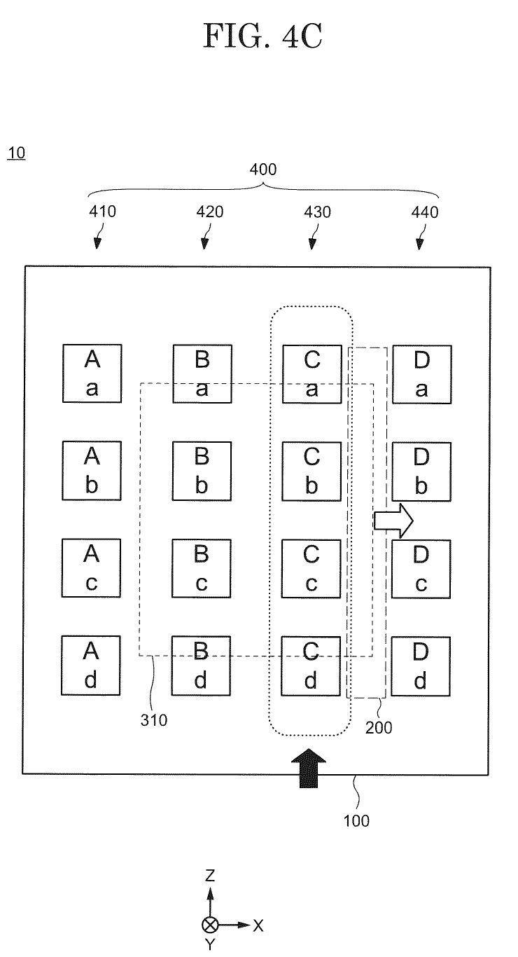

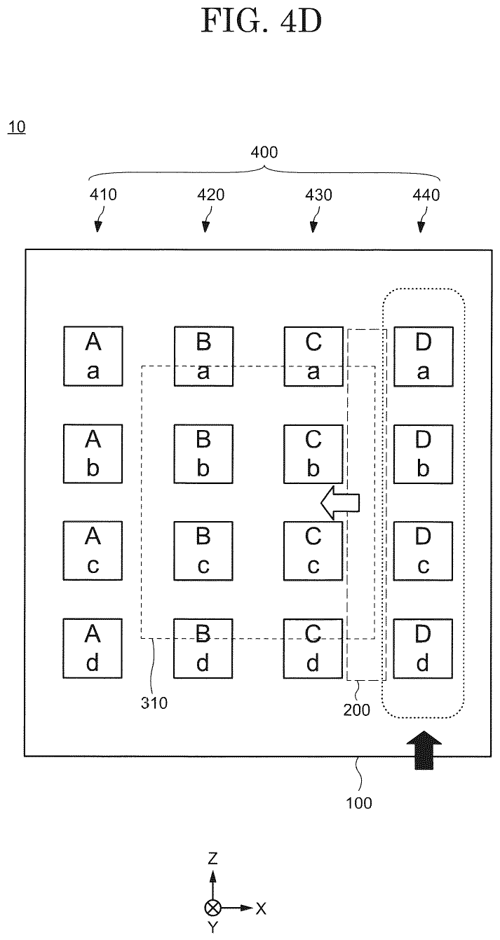

A sputtering method using the sputtering apparatus 10 according to an embodiment of the present invention will be described with reference to FIG. 4A and FIG. 4D. Since the configuration of the sputtering apparatus 10 used in the present embodiment is the same as the configuration of the sputtering apparatus 10 shown in FIG. 1, a description thereof will be omitted. In the present embodiment, an embodiment in which the GaN layer is formed using the sputtering apparatus 10 in which the GaN is used as the target 210 will be described.

### [2-1. Sputtering Method]

FIG. 4A to FIG. 4D are diagrams showing a sputtering method according to an embodiment of the present invention. In these figures, the target portion 200 moves from the positions shown in the respective drawings in the direction of the white arrows. In these figures, the radical irradiation apparatuses in the column surrounded by a substantially rectangular dotted line with rounded corners and indicated by the black arrows are the selected radical irradiation apparatuses. The radical irradiation apparatuses are the on-state radical irradiation apparatuses (the radical irradiation apparatuses not surrounded by a dotted line are the off-state radical irradiation apparatuses) or the radical irradiation apparatuses having a higher amount of radical generation than other radical irradiation apparatuses. The position of the target portion 200 and the operation of each radical irradiation apparatus 400 in the following explanation are realized by the control device 600, the position control device 610, and the moving mechanism 620 shown in FIG. 1 and FIG. 3.

As shown in FIG. 4A, the target portion 200 moves in a direction away from the radical irradiation apparatuses Aa˜Ad and in a direction approaching the radical irradiation apparatuses Ba˜Bd. In this state, the radical irradiation apparatuses Aa˜Ad are selected. The selected radical irradiation apparatuses Aa˜Ad are in the on-state and the other radical irradiation apparatuses (Ba˜Bd, Ca˜Cd, Da˜Dd) are in the off-state. Alternatively, the amount of radicals generated by the selected radical irradiation apparatuses Aa˜Ad is greater than the amount of radicals generated by the other radical irradiation apparatuses (Ba˜Bd, Ca˜Cd, Da˜Dd). In FIG. 4A, the target portion 200 does not overlap the radical irradiation apparatuses Aa˜Ad in a plan view with respect to the deposition surface of the substrate 310.

As shown in FIG. 4B, the target portion 200 moves in a direction away from the radical irradiation apparatuses Ba˜Bd and in a direction approaching the radical irradiation apparatuses Ca˜Cd. In this state, the radical irradiation apparatuses Ba˜Bd are selected. The selected radical irradiation apparatuses Ba˜Bd are in the on-state and the other radical irradiation apparatuses (Aa˜Ad, Ca˜Cd, Da˜Dd) are in the off-state. Alternatively, the amount of radicals generated by the selected radical irradiation apparatuses Ba˜Bd is greater than the amount of radicals generated by the other radical irradiation apparatuses (Aa˜Ad, Ca˜Cd, Da˜Dd). In FIG. 4B, the target portion 200 does not overlap the radical irradiation apparatuses Ba˜Bd in a plan view with respect to the deposition surface of the substrate 310.

As shown in FIG. 4C, the target portion 200 moves in a direction away from the radical irradiation apparatuses Ca˜Cd and in a direction approaching the radical irradiation apparatuses Da˜Dd. In this state, the radical irradiation apparatuses Ca˜Cd are selected. The selected radical irradiation apparatuses Ca˜Cd are in the on-state and the other radical irradiation apparatuses (Aa˜Ad, Ba˜Bd, Da˜Dd) are in the off-state. Alternatively, the amount of radicals generated by the selected radical irradiation apparatuses Ca˜Cd is greater than the amount of radicals generated by the other radical irradiation apparatuses (Aa˜Ad, Ba˜Bd, Da˜Dd). In FIG. 4C, the target portion 200 does not overlap the radical irradiation apparatuses Ca˜Cd in a plan view with respect to the deposition surface of the substrate 310.

As shown in FIG. 4D, the target portion 200 is folded back at the right end of the substrate 310 and moves in a direction away from the radical irradiation apparatuses Da˜Dd and in the direction approaching the radical irradiation apparatuses Ca˜Cd. In this state, the radical irradiation apparatuses Da˜Dd are selected. The selected radical irradiation apparatuses Da˜Dd are in the on-state and the other radical irradiation apparatuses (Aa˜Ad, Ba˜Bd, Ca˜Cd) are in the off-state. Alternatively, the amount of radicals generated by the selected radical irradiation apparatuses Da˜Dd is greater than the amount of radicals generated by the other radical irradiation apparatuses (Aa˜Ad, Ba˜Bd, Ca˜Cd). In FIG. 4D, the target portion 200 does not overlap the radical irradiation apparatuses Da˜Dd in a plan view with respect to the deposition surface of the substrate 310.

As described above, in the sputtering method according to the present embodiment, when viewed in the Y-axis direction, the target portion 200 moves in a region overlapping the plurality of radical irradiation apparatuses 400 in the X-axis direction. Then, when viewed in the Y-axis direction, the radical irradiation apparatuses of a specific column unit selected as described above are selected to follow the movement of the target portion 200. In other words, the radical irradiation apparatuses of a specific column unit selected as described above are sequentially switched in the X-axis direction according to the positional relationship between the substrate 310 and the target portion 200 in the X-axis direction.

As described above, when the GaN layer is deposited by the sputtering method using the GaN target, the nitrogen-depleted GaN layer tends to be formed. However, according to the sputtering method of the present embodiment, the radical irradiation is performed after the GaN layer is formed, so that nitrogen can be replenished in the GaN layer.

### 3. Third Embodiment

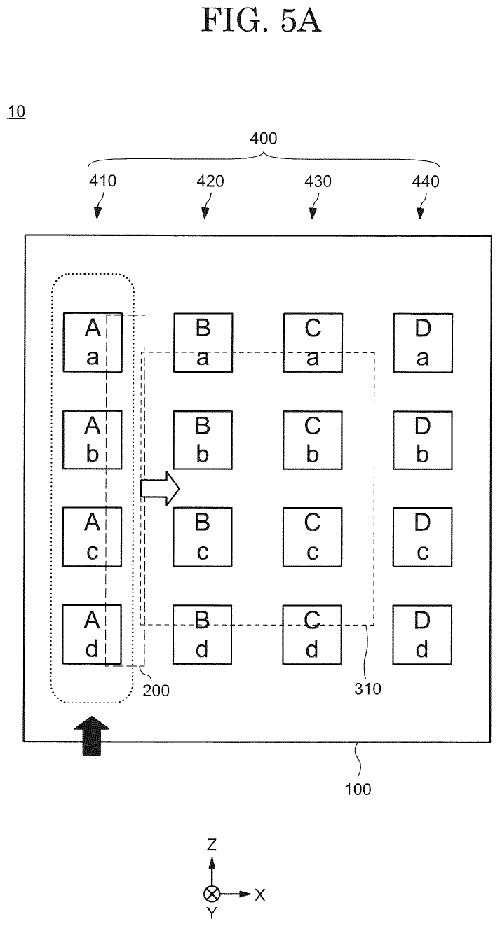

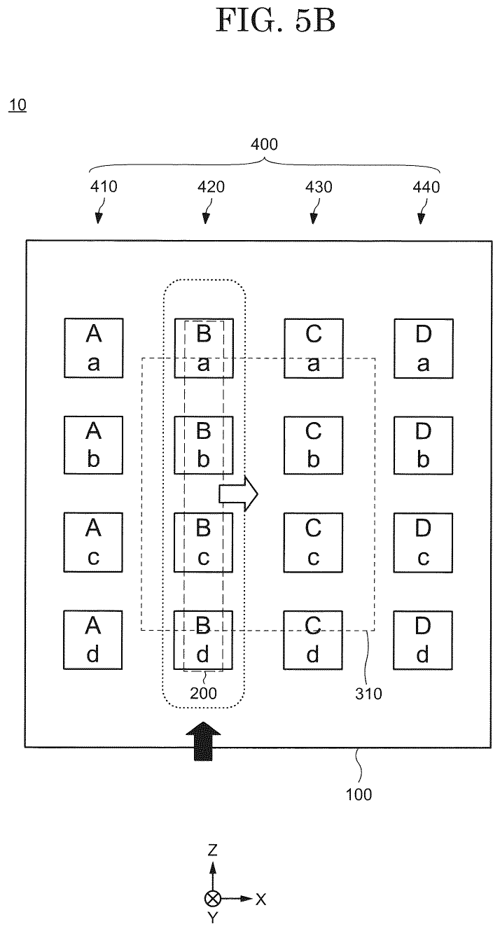

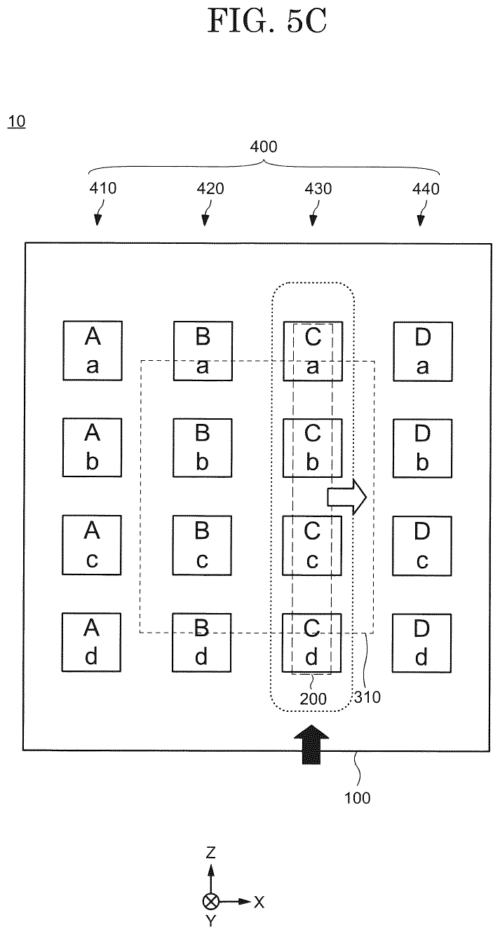

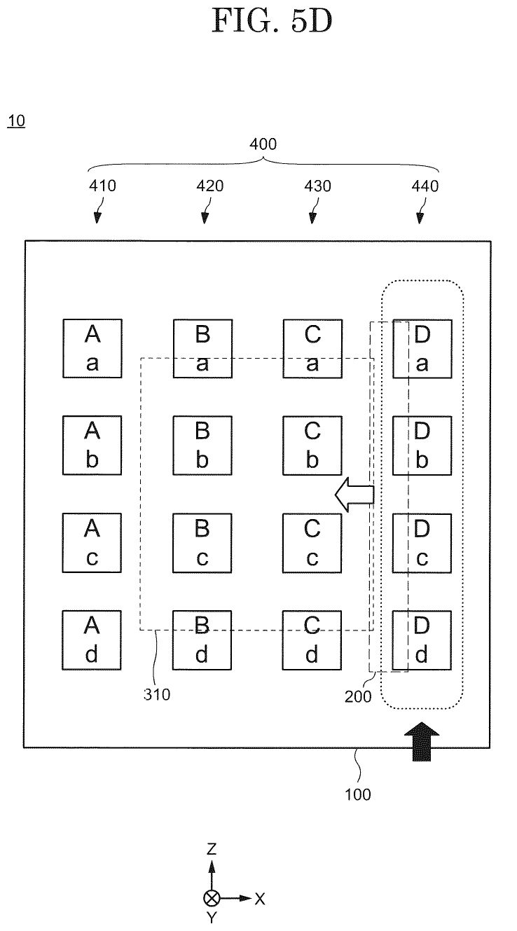

A sputtering method using the sputtering apparatus 10 according to an embodiment of the present invention will be described with reference to FIG. 5A and FIG. 5D. Since the configuration of the sputtering apparatus 10 used in the present embodiment is the same as the configuration of the sputtering apparatus 10 shown in FIG. 1, a description thereof will be omitted. In the present embodiment, an embodiment in which the GaN layer is formed using the sputtering apparatus 10 in which the Ga is used as the target 210 will be described.

### [3-1. Sputtering Method]

FIG. 5A to FIG. 5D are diagrams showing a sputtering method according to an embodiment of the present invention. In these figures, the target portion 200 moves from the positions shown in the respective drawings in the direction of the white arrows. In these figures, the radical irradiation apparatuses in the column surrounded by a substantially rectangular dotted line with rounded corners and indicated by the black arrows are the on-state radical irradiation apparatuses (the radical irradiation apparatuses in the region not surrounded by dotted lines are in the off-state) or the radical irradiation apparatuses having a higher amount of radical generation than other radical irradiation apparatuses. The position of the target portion 200 and the operation of the radical irradiation apparatus 400 in the following explanation are realized by the control device 600, the position control device 610, and the moving mechanism 620 shown in FIG. 1 and FIG. 3.

As shown in FIG. 5A, the target portion 200 moves from the region overlapping the radical irradiation apparatuses Aa˜Ad toward the direction approaching the radical irradiation apparatuses Ba˜Bd. In this state, the radical irradiation apparatuses Aa˜Ad are selected. The selected radical irradiation apparatuses Aa˜Ad are in the on-state and the other radical irradiation apparatuses (Ba˜Bd, Ca˜Cd, Da˜Dd) are in the off-state. Alternatively, the amount of radicals generated by the selected radical irradiation apparatuses Aa˜Ad is greater than the amount of radicals generated by the other radical irradiation apparatuses (Ba˜Bd, Ca˜Cd, Da˜Dd). In FIG. 5A, the target portion 200 overlaps the radical irradiation apparatuses Aa˜Ad in a plan view with respect to the deposition surface of the substrate 310.

As shown in FIG. 5B, the target portion 200 moves from the region overlapping the radical irradiation apparatuses Ba˜Bd toward the direction approaching the radical irradiation apparatuses Ca˜Cd. In this state, the radical irradiation apparatuses Ba˜Bd are selected. The selected radical irradiation apparatuses Ba˜Bd are in the on-state and the other radical irradiation apparatuses (Aa˜Ad, Ca˜Cd, Da˜Dd) are in the off-state. Alternatively, the amount of radicals generated by the selected radical irradiation apparatuses Ba˜Bd is greater than the amount of radicals generated by the other radical irradiation apparatuses (Aa˜Ad, Ca˜Cd, Da˜Dd). In FIG. 5B, the target portion 200 overlaps the radical irradiation apparatuses Ba˜Bd in a plan view with respect to the deposition surface of the substrate 310.

As shown in FIG. 5C, the target portion 200 moves from the region overlapping the radical irradiation apparatuses Ca˜Cd toward the direction approaching the radical irradiation apparatuses Da˜Dd. In this state, the radical irradiation apparatuses Ca˜Cd are selected. The selected radical irradiation apparatuses Ca˜Cd are in the on-state and the other radical irradiation apparatuses (Aa˜Ad, Ba˜Bd, Da˜Dd) are in the off-state. Alternatively, the amount of radicals generated by the selected radical irradiation apparatuses Ca˜Cd is greater than the amount of radicals generated by the other radical irradiation apparatuses (Aa˜Ad, Ba˜Bd, Da˜Dd). In FIG. 5C, the target portion 200 overlaps the radical irradiation apparatuses Ca˜Cd in a plan view with respect to the deposition surface of the substrate 310.

As shown in FIG. 5D, the target portion 200 is folded back at the right end of the substrate 310 and moves from the region overlapping the radical irradiation apparatuses Da˜Dd toward the direction approaching the radical irradiation apparatuses Ca˜Cd. In this state, the radical irradiation apparatuses Da˜Dd are selected. The selected radical irradiation apparatuses Da˜Dd are in the on-state and the other radical irradiation apparatuses (Aa˜Ad, Ba˜Bd, Ca˜Cd) are in the off-state. Alternatively, the amount of radicals generated by the selected radical irradiation apparatuses Da˜Dd is greater than the amount of radicals generated by the other radical irradiation apparatuses (Aa˜Ad, Ba˜Bd, Ca˜Cd). In FIG. 5D, the target portion 200 overlaps the radical irradiation apparatuses Da˜Dd in a plan view with respect to the deposition surface of the substrate 310.

As described above, in the sputtering method according to the present embodiment, when viewed in the Y-axis direction, the target portion 200 moves in the region overlapping the plurality of radical irradiation apparatuses 400 in the X-axis direction. Then, when viewed in the Y-axis direction, the radical irradiation apparatuses of a specific column unit selected as described above are selected to overlap the target portion 200. In other words, the radical irradiation apparatuses of a specific column unit selected as described above are sequentially switched in the X-axis direction according to the positional relationship between the substrate 310 and the target portion 200 in the X-axis direction.

As described above, when the GaN layer is formed by the sputtering method using the Ga target, the GaN layer can be formed by reactive sputtering in which radical irradiation is performed simultaneously with the deposition of Ga.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A sputtering apparatus comprising:
a substrate hold portion holding a substrate;
a target facing the substrate hold portion and configured to move to a first direction in a relative positional relationship with the substrate hold portion; and
a plurality of radical irradiation apparatuses, irradiation positions of radicals from the plurality of radical irradiation apparatuses on a deposition surface of the substrate being different,
wherein the plurality of radical irradiation apparatuses is configured to individually adjust an amount of radical generation.

2. The sputtering apparatus according to claim 1, wherein
the target has a longitudinal in a second direction perpendicular to the first direction, and
the deposition surface expands in the first direction and the second direction.

3. The sputtering apparatus according to claim 2, wherein
the plurality of radical irradiation apparatuses includes a first radical irradiation apparatus and a second radical irradiation apparatus arranged in the first direction, and
the first radical irradiation apparatus and the second radical irradiation apparatus are configured to individually adjust an amount of radical generation.

4. The sputtering apparatus according to claim 3, wherein
the plurality of radical irradiation apparatuses includes a third radical irradiation apparatus arranged in the second direction with respect to the first radical irradiation apparatus,
different gases are provided to the first radical irradiation apparatus and the third radical irradiation apparatus, and
the first radical irradiation apparatus and the third radical irradiation apparatus irradiate different kinds of radicals based on the provided gas.

5. The sputtering apparatus according to claim 3, wherein
the plurality of radical irradiation apparatuses includes a third radical irradiation apparatus arranged in the second direction with respect to the first radical irradiation apparatus, and
the first radical irradiation apparatus and the third radical irradiation apparatus are configured to individually adjust an amount of radical generation.

6. The sputtering apparatus according to claim 2, wherein
the plurality of radical irradiation apparatuses includes a first radical irradiation apparatus and a second radical irradiation apparatus arranged in the first direction,
different gases are provided to the first radical irradiation apparatus and the second radical irradiation apparatus, and
the first radical irradiation apparatus and the second radical irradiation apparatus irradiate different kinds of radicals based on the provided gas.

7. The sputtering apparatus according to claim 5, wherein
the plurality of radical irradiation apparatuses includes a third radical irradiation apparatus arranged in the second direction with respect to the first radical irradiation apparatus,
different gases are provided to the first radical irradiation apparatus and the third radical irradiation apparatus, and
the first radical irradiation apparatus and the third radical irradiation apparatus irradiate different kinds of radicals based on the provided gas.

8. The sputtering apparatus according to claim 2, wherein
the plurality of radical irradiation apparatuses is arranged in the first direction and the second direction, and
the amount of radical generation is for each column unit arranged in the second direction in the plurality of radical irradiation apparatuses.

9. The sputtering apparatus according to claim 8, wherein
the amount of radical generation is adjustable for a first column unit or a second column unit arranged in the second direction in the plurality of radical irradiation apparatuses, and
an amount of radicals generated by the radical irradiation apparatuses in the first column unit is greater than an amount of radicals generated by the radical irradiation apparatuses in the second column unit.

10. The sputtering apparatus according to claim 9, wherein
the radical irradiation apparatuses in the first column unit are sequentially switched in the first direction.

11. The sputtering apparatus according to claim 9, wherein
the radical irradiation apparatuses in the first column unit are sequentially switched in the first direction according to a positional relationship between the substrate and the target in the first direction.

12. The sputtering apparatus according to claim 9, wherein
an amount of radicals generated by the radical irradiation apparatuses in the second column unit is 30% or less of an amount of radicals generated by the radical irradiation apparatuses in the first column unit.

13. The sputtering apparatus according to claim 12, wherein
the radical irradiation apparatuses in the first column unit are sequentially switched in the first direction.

14. The sputtering apparatus according to claim 12, wherein
the radical irradiation apparatuses in the first column unit are sequentially switched in the first direction according to a positional relationship between the substrate and the target in the first direction.

15. The sputtering apparatus according to claim 14, wherein
the target is configured to move in the first direction in a region overlapping the plurality of radical irradiation apparatuses in a view from a third direction perpendicular to the first direction and the second direction, and
the radical irradiation apparatuses in the first column unit are selected to follow a movement of the target in a view from the third direction.

16. The sputtering apparatus according to claim 14, wherein
the target is configured to move in the first direction in a region overlapping the plurality of radical irradiation apparatuses in a view from a third direction perpendicular to the first direction and the second direction, and
the radical irradiation apparatuses in the first column unit are selected to overlap the target in a view from the third direction.

17. The sputtering apparatus according to claim 1, wherein the target is a flat plate type target.

18. The sputtering apparatus according to claim 1, wherein the target is a rotary target.
